(19) United States
(12) Patent Application Publication
(10) Pub. No.: US 2026/0262506 A1
(43) Pub. Date: Sep. 3, 2026

(54) SEMICONDUCTOR DEVICE AND METHOD OF MANUFACTURING THE SAME

(71) Applicant: Kioxia Corporation, Tokyo (JP)

(72) Inventors: Satoshi MATSUDA, Yokkaichi Mie (JP); Junichi SHIBATA, Yokkaichi Mie (JP)

(73) Assignee: Kioxia Corporation, Tokyo (JP)

(21) Appl. No.: 19/228,930

(22) Filed: Jun. 5, 2025

(30) Foreign Application Priority Data
Feb. 28, 2025 (JP) 2025-032065

(51) Int. Cl. H01L 23/544; H01L 23/00

(52) U.S. Cl. CPC H10W 46/00; H10W 46/301; H10W 80/168; H10W 90/792

(57) ABSTRACT

In one embodiment, a semiconductor device includes a lower substrate including a first substrate, a first insulator provided on the first substrate, a first pad provided in the first insulator on an upper face side of the first insulator, and a first concave portion provided in the first insulator on the upper face side of the first insulator. The device further includes an upper substrate disposed on the lower substrate and in contact with the lower substrate, the upper substrate including a second substrate, a second insulator provided below the second substrate, a second pad provided in the second insulator on a lower face side of the second insulator, and a second concave portion provided in the second insulator on the lower face side of the second insulator and facing the first concave portion. The device further includes a first member housed in the first and second concave portions.

### CROSS REFERENCE TO RELATED APPLICATION

This application is based upon and claims the benefit of priority from the prior Japanese Patent Application No. 2025-032065, filed on Feb. 28, 2025, the entire contents of which are incorporated herein by reference.

### FIELD

Embodiments described herein relate to a semiconductor device and a method of manufacturing the same.

### BACKGROUND

When a semiconductor device is manufactured by bonding a plurality of wafers, it is required to bond the wafers with high accuracy.

### BRIEF DESCRIPTION OF THE DRAWINGS

FIG. 1 is a cross sectional view illustrating the structure of a semiconductor device of a first embodiment;

FIGS. 2A and 2B are plan views illustrating the structure of the semiconductor device of the first embodiment;

FIG. 3 is a perspective view illustrating a method of manufacturing the semiconductor device of the first embodiment;

FIGS. 4A and 4B are perspective views illustrating an example of the method of manufacturing the semiconductor device of the first embodiment;

FIGS. 5A and 5B are perspective views illustrating another example of the method of manufacturing the semiconductor device of the first embodiment;

FIG. 6 is a perspective view illustrating the method of manufacturing the semiconductor device of the first embodiment;

FIGS. 7A to 7D are cross sectional views illustrating a method of manufacturing a semiconductor device of a first modification of the first embodiment;

FIGS. 8 to 10 are cross sectional views illustrating a method of manufacturing a semiconductor device of a second modification of the first embodiment;

FIGS. 11A to 11C are cross sectional views for describing methods of manufacturing semiconductor devices of third to fifth modifications of the first embodiment;

FIGS. 12A and 12B are plan views for describing a method of manufacturing a semiconductor device of a sixth modification of the first embodiment;

FIG. 13 is a perspective view illustrating a method of manufacturing a semiconductor device of a seventh modification of the first embodiment;

FIG. 14 is a plan view illustrating the structure of a semiconductor device of an eighth modification of the first embodiment;

FIG. 15 is a cross sectional view illustrating the structure of a semiconductor device of a second embodiment;

FIG. 16 is an enlarged cross sectional view illustrating the structure of the semiconductor device of the second embodiment; and

FIGS. 17 and 18 are cross sectional views illustrating a method of manufacturing the semiconductor device of the second embodiment.

### DETAILED DESCRIPTION

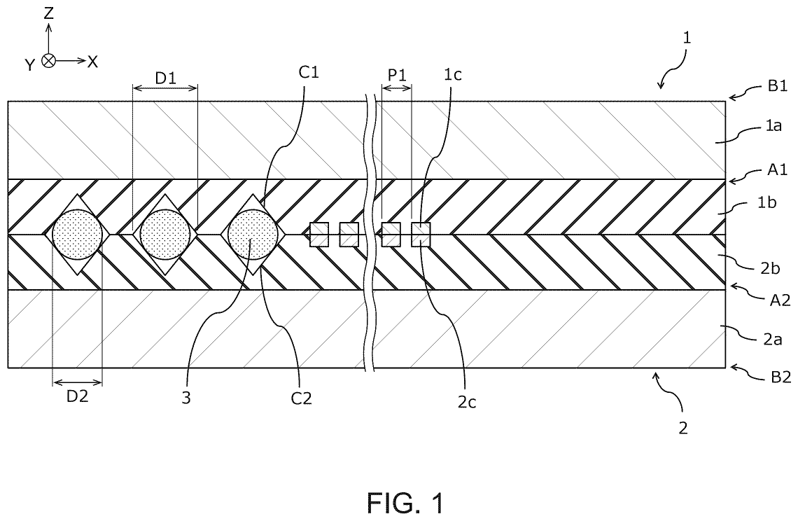

Embodiments will now be explained with reference to the accompanying drawings. The same components in FIGS. 1 to 18 are denoted by the same reference sign, and duplicate description of components is omitted.

In one embodiment, a semiconductor device includes a lower substrate including a first substrate, a first insulator provided on the first substrate, a first pad provided in the first insulator on an upper face side of the first insulator, and a first concave portion provided in the first insulator on the upper face side of the first insulator. The device further includes an upper substrate disposed on the lower substrate and in contact with the lower substrate, the upper substrate including a second substrate, a second insulator provided below the second substrate, a second pad provided in the second insulator on a lower face side of the second insulator, and a second concave portion provided in the second insulator on the lower face side of the second insulator and facing the first concave portion. The device further includes a first member housed in the first concave portion and the second concave portion.

### First Embodiment

FIG. 1 is a cross sectional view illustrating the structure of a semiconductor device of a first embodiment.

The semiconductor device of the present embodiment includes an upper substrate 1, a lower substrate 2, and a plurality of spherical members 3 that is an example of a first member. The upper substrate 1 is bonded to the lower substrate 2. Accordingly, the upper substrate 1 is disposed on the lower substrate 2 and in contact with the lower substrate 2. The semiconductor device of the present embodiment is, for example, a semiconductor chip including a three-dimensional semiconductor memory.

The upper substrate 1 includes a substrate 1a that is an example of a second substrate, an inter layer dielectric 1b that is an example of a second insulator and a second film, and a plurality of metal pads 1c that is an example of a second pad. The lower substrate 2 includes a substrate 2a that is an example of a first substrate, an inter layer dielectric 2b that is an example of a first insulator and a first film, and a plurality of metal pads 2c that is an example of a first pad. In a case where the semiconductor device of the present embodiment is a semiconductor chip, the upper substrate 1 is an upper chip in the semiconductor chip, and the lower substrate 2 is a lower chip in the semiconductor chip.

Each of the substrates 1a and 2a is, for example, a semiconductor substrate such as a silicon (Si) substrate. FIG. 1 illustrates a lower face A1 and an upper face B1 of the substrate 1a, and an upper face A2 and a lower face B2 of the substrate 2a. FIG. 1 also illustrates an X direction and a Y direction that are parallel to the faces A1, B1, A2, and B2 and orthogonal to each other, and a Z direction that is orthogonal to the faces A1, B1, A2, and B2. In the present specification, a positive Z direction is an upward direction, and a negative Z direction is a downward direction. The negative Z direction may or may not be aligned with the direction of gravity.

The inter layer dielectric 1b is provided below the substrate 1a, and the inter layer dielectric 2b is provided on the substrate 2a. Each of the inter layer dielectrics 1b and 2b is, for example, a stacked insulator including a silicon oxide film (SiO₂ film) and other insulators. In the present embodiment, a lower face of the inter layer dielectric 1b and an upper face of the inter layer dielectric 2b are formed of SiO₂. The inter layer dielectric 1b of the present embodiment is bonded to the inter layer dielectric 2b. Accordingly, the inter layer dielectric 1b is disposed on the inter layer dielectric 2b, and the lower face of the inter layer dielectric 1b is in contact with the upper face of the inter layer dielectric 2b.

Each metal pad 1c is provided in the inter layer dielectric 1b on the lower face side of the inter layer dielectric 1b, and each metal pad 2c is provided in the inter layer dielectric 2b on the upper face side of the inter layer dielectric 2b. Each of the metal pads 1c and 2c is, for example, a metal layer including a copper (Cu) layer. Each metal pad 1c of the present embodiment is bonded to the corresponding metal pad 2c. Accordingly, each metal pad 1c is disposed on the corresponding metal pad 2c, and a lower face of each metal pad 1c is in contact with an upper face of the corresponding metal pad 2c. The semiconductor device of the present embodiment may include a metal pad (dummy pad) 1c in contact with no metal pad 2c, and a metal pad (dummy pad) 2c in contact with no metal pad 1c.

The upper substrate 1 also includes a plurality of concave portions C1 provided in the inter layer dielectric 1b on the lower face side of the inter layer dielectric 1b. The concave portions C1 are holes formed in the inter layer dielectric 1b. Each concave portion C1 has, for example, a conical or pyramidal shape. Accordingly, the surface of each concave portion C1 has a tapered shape that is tilted relative to an XY plane. In the present embodiment, the shape of each concave portion C1 is a conical or pyramidal shape extending in the Z direction, and the shape of each concave portion C1 in a plan view is a circular or polygonal shape (for example, a quadrilateral such as a square or a rectangle). In FIG. 1, the surface of each concave portion C1 is formed of the inter layer dielectric 1b. Each concave portion C1 is an example of a second concave portion.

The lower substrate 2 also includes a plurality of concave portions C2 provided in the inter layer dielectric 2b on the upper face side of the inter layer dielectric 2b. The concave portions C2 are holes formed in the inter layer dielectric 2b. Each concave portion C2 has, for example, a conical or pyramidal shape. Accordingly, the surface of each concave portion C2 has a tapered shape that is tilted relative to an XY plane. In the present embodiment, the shape of each concave portion C2 is a conical or pyramidal shape extending in the Z direction, and the shape of each concave portion C2 in a plan view is a circular or polygonal shape (for example, a quadrilateral such as a square or a rectangle). In FIG. 1, the surface of each concave portion C2 is formed of the inter layer dielectric 2b. Each concave portion C2 is an example of a first concave portion.

In FIG. 1, each concave portion C1 is disposed on the corresponding concave portion C2 and faces the corresponding concave portion C2. As a result, each pair of concave portions C1 and C2 forms one hollow space in the inter layer dielectrics 1b and 2b. FIG. 1 illustrates three hollow spaces formed of three pairs of concave portions C1 and C2. In the present embodiment, the shapes of the above-described plurality of concave portions C1 are identical, the shapes of the above-described plurality of concave portions C2 are identical, and the shape of each concave portion C1 in a plan view and the shape of each concave portion C2 in a plan view are congruent. Accordingly, in a case where the shapes of the concave portions C1 and C2 are, for example, triangular pyramids (tetrahedrons), the shape of each hollow space is a hexahedron when the concave portions C1 and C2 are aligned without displacement. In a case where the shapes of the concave portions C1 and C2 are, for example, square pyramids (pentahedrons), the shape of each hollow space is an octahedron when the concave portions C1 and C2 are aligned without displacement.

Each spherical member 3 is housed in one hollow space formed of a pair of concave portions C1 and C2. FIG. 1 illustrates three spherical members 3 housed in three hollow spaces. Each spherical member 3 has a spherical shape. The shape of each spherical member 3 may be a nearly perfect sphere or a sphere with a large deviation from a perfect sphere. Each spherical member 3 is formed of, for example, glass or metal. An example of each spherical member 3 is a glass bead formed of glass or a metal ball formed of metal. Each spherical member 3 may be an elastic member formed of an elastic material. In each hollow space of the present embodiment, the spherical member 3 is housed in the concave portions C1 and C2 in a state of being in contact with both the surface of the concave portion C1 and the surface of the concave portion C2, in other words, in a state of being in contact with both the inter layer dielectrics 1b and 2b.

In the present embodiment, the upper substrate 1 and the lower substrate 2 are bonded such that one or more spherical members 3 are housed in one or more pairs of concave portions C1 and C2, respectively. Thus, alignment between the upper substrate 1 and the lower substrate 2 can be achieved by means of these spherical members 3. Accordingly, the upper substrate 1 and the lower substrate 2 can be bonded with high accuracy, which makes it possible to improve a yield resulting from a bonding process between the upper substrate 1 and the lower substrate 2 and to reduce cost attributable to the bonding process.

For example, alignment between the upper substrate 1 and the lower substrate 2 may be performed by optical measurement. However, in a case where optical measurement is employed, small sizes of the metal pads 1c and 2c, light transmission through the upper substrate 1 and the lower substrate 2, and potential distortion occurring in the upper substrate 1 and the lower substrate 2 hinder preferable optical measurement. As a result, highly accurate and highly difficult adjustment is needed for optical measurement. Furthermore, in a case where optical measurement is performed by using, for example, X-ray, high cost of an X-ray device also becomes a problem.

However, the present embodiment makes it possible to prevent such a problem by performing alignment between the upper substrate 1 and the lower substrate 2 without using optical measurement. This makes it possible to excellently bond the upper substrate 1 and the lower substrate 2.

The size, shape, and material of each spherical member 3 of the present embodiment may be optional but are desirably suitable for alignment. For example, in order to fix a positional relation between the upper substrate 1 and the lower substrate 2, the size of each spherical member 3 is desirably a size with which the spherical member 3 moves as little as possible in the hollow space. Thus, the size of each spherical member 3 is desirably a size with which the spherical member 3 is housed in the concave portions C1 and C2 in a state of being in contact with both the inter layer dielectrics 1b and 2b. Moreover, each spherical member 3 may be replaced with a member having an optional shape, and the member desirably has a spherical shape, rather than an aspherical shape, so that the orientation of the member is unlikely to change in the hollow space. In other words, the member is desirably a sphere (spherical object). The shape of the member may be an aspherical shape but is desirably a highly symmetric shape like a spherical shape.

Each spherical member 3 may be formed of a highly rigid material or an elastic material. An example of the highly rigid material is glass (SiO₂). In this case, each spherical member 3 and the inter layer dielectrics 1b and 2b forming the concave portions C1 and C2 can be formed of the same material SiO₂. In a case where each spherical member 3 is formed of an elastic material, the size of the spherical member 3 may be larger than a size with which the spherical member 3 fits the hollow space in a state in which no external force is applied to the spherical member 3. This makes it possible to house each spherical member 3 in the hollow space such that the spherical member 3 is compressed in the hollow space, and fix the positional relation between the upper substrate 1 and the lower substrate 2 by elastic force.

FIG. 1 also illustrates a pitch P1 between the metal pads 1c and between the metal pad 2c, a width D1 of each of the concave portions C1 and C2 in a plan view, and a width D2 of each spherical member 3 in a plan view. In the present embodiment, each spherical member 3 has a spherical shape, and the width D2 is the diameter of the spherical shape. In a case where each of the concave portions C1 and C2 has a conical shape, the width D1 is the diameter of the base of the conical shape.

The pitch P1 is, for example, 1.0 to 2.0 μm. The width D1 is, for example, 10 to 50 μm. The width D2 is, for example, 20 μm or smaller. In a case where hybrid bonding is employed as in the present embodiment, in which the inter layer dielectric 1b is bonded to the inter layer dielectric 2b and the metal pads 1c are bonded to the metal pads 2c, it is desirable to ensure approximately 1/10 of the above-described pitch P1 for an alignment accuracy between the upper substrate 1 and the lower substrate 2. In this case, the width D2 is desirably equal to or smaller than 10 times the pitch P1, and thus, is desirably 20 μm or smaller as described above. This makes it possible to excellently perform alignment between the upper substrate 1 and the lower substrate 2 by self-alignment.

A method of the present embodiment is applicable not only to a case where two substrates (the upper substrate 1 and the lower substrate 2) are bonded but also to a case where three or more substrates are bonded. Moreover, the upper substrate 1 and the lower substrate 2 may be an array substrate including a memory cell array, and a circuit board including a control circuit therefor, or may be both array substrates. In addition, the size of the upper substrate 1 in a plan view and the size of the lower substrate 2 in a plan view are the same in the present embodiment but may be different.

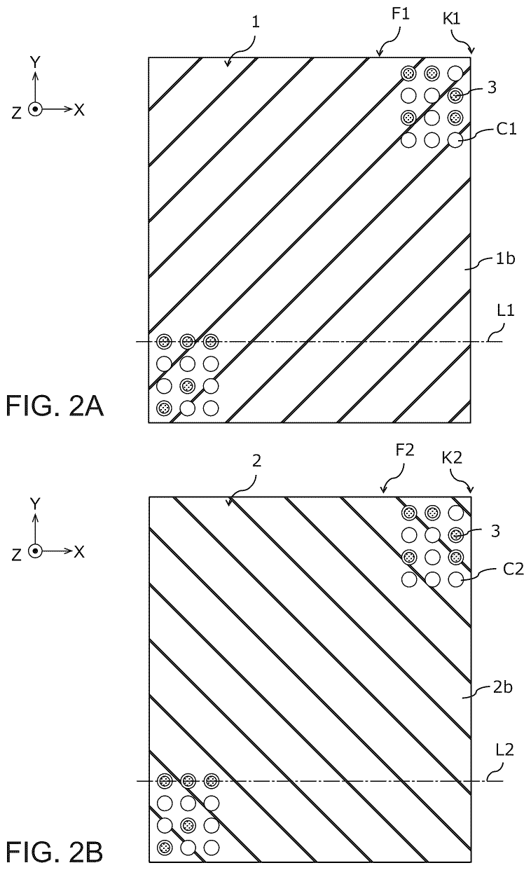

FIGS. 2A and 2B are plan views illustrating the structure of the semiconductor device of the first embodiment.

FIG. 2A illustrates the inter layer dielectric 1b and the plurality of concave portions C1 in the upper substrate 1 and also illustrates the plurality of spherical members 3 in the concave portions C1. FIG. 1 illustrates a section along a straight line L1 illustrated in FIG. 2A.

The semiconductor device of the present embodiment is a semiconductor chip, and the shapes of the substrate 1a and the inter layer dielectric 1b in a plan view are each a quadrilateral such as a square or a rectangle as illustrated in FIG. 2A. FIG. 2A illustrates four sides F1 and four corners K1 of the quadrilateral. In FIG. 2A, the above-described plurality of concave portions C1 include 12 concave portions C1 provided near the upper-right corner K1, and 12 concave portions C1 provided near the lower-left corner K1. The lower-left corner K1 is positioned on a diagonal line of above-described quadrilateral with respect to the upper-right corner K1. The upper-right corner K1 is an example of a first corner, and the lower-left corner K1 is an example of a second corner.

FIG. 2A illustrates 10 spherical members 3. These spherical members 3 are housed in some of the concave portions C1 provided near the upper-right corner K1 and some of the concave portions C1 provided near the lower-left corner K1. In FIG. 2A, spherical members 3 may be housed in all concave portions C1.

FIG. 2B illustrates the inter layer dielectric 2b and the plurality of concave portions C2 in the lower substrate 2, and also illustrates the plurality of spherical members 3 in the concave portions C2. FIG. 1 illustrates a section along a straight line L2 illustrated in FIG. 2B.

The semiconductor device of the present embodiment is a semiconductor chip as described above, and the shapes of the substrate 2a and the inter layer dielectric 2b in a plan view are each a quadrilateral such as a square or a rectangle as illustrated in FIG. 2B. FIG. 2B illustrates four sides F2 and four corners K2 of the quadrilateral. The quadrilateral illustrated in FIG. 2B is congruent to the quadrilateral illustrated in FIG. 2A. In FIG. 2B, the above-described plurality of concave portions C2 include 12 concave portions C2 provided near the upper-right corner K2, and 12 concave portions C2 provided near the lower-left corner K2. The lower-left corner K2 is positioned on a diagonal line of the above-described quadrilateral with respect to the upper-right corner K2. The upper-right corner K2 is an example of the first corner, and the lower-left corner K2 is an example of the second corner.

FIG. 2B illustrates 10 spherical members 3. These spherical members 3 are housed in some of the concave portions C2 provided near the upper-right corner K2 and some of the concave portions C2 provided near the lower-left corner K2. In FIG. 2B, spherical members 3 may be housed in all concave portions C2.

The semiconductor device of the present embodiment includes spherical members 3 in the concave portions C1 and C2 provided near the upper-right corners K1 and K2, and spherical members 3 in the concave portions C1 and C2 provided near the lower-left corners K1 and K2. This makes it possible to fix the positional relation between the upper substrate 1 and the lower substrate 2 by the spherical members 3 at the upper-right corners K1 and K2 and the spherical members 3 at the lower-left corners K1 and K2. Moreover, since the upper-right corners K1 and K2 and the lower-left corners K1 and K2 are positioned on a diagonal line, the positional relation between the upper substrate 1 and the lower substrate 2 can be fixed so as to prevent rotation of the upper substrate 1 relative to the lower substrate 2.

The pitches between the concave portions C1 in the X direction and the Y direction are constant near the upper-right corner K1 illustrated in FIG. 2A. Similarly, the pitches between the concave portions C1 in the X direction and the Y direction are constant near the lower-left corner K1 illustrated in FIG. 2A. However, these pitches may not be constant. This is also the same for the concave portions C2 illustrated in FIG. 2B. In the present embodiment, the pitch between the concave portions C2 is the same as the pitch between the concave portions C1.

Disposition of the plurality of concave portions C1 in the inter layer dielectric 1b may be different from disposition illustrated in FIG. 2A. For example, the concave portions C1 may be disposed not only near the upper-right corner K1 and the lower-left corner K1 of the above-described quadrilateral but also near the lower-right corner K1 and the upper-left corner K1 of the above-described quadrilateral. However, the concave portions C1 are desirably disposed at positions not interfering with disposition of the metal pads 1c and are desirably disposed, for example, near one or more sides F1 of the above-described quadrilateral. This is also the same for the concave portions C2 illustrated in FIG. 2B.

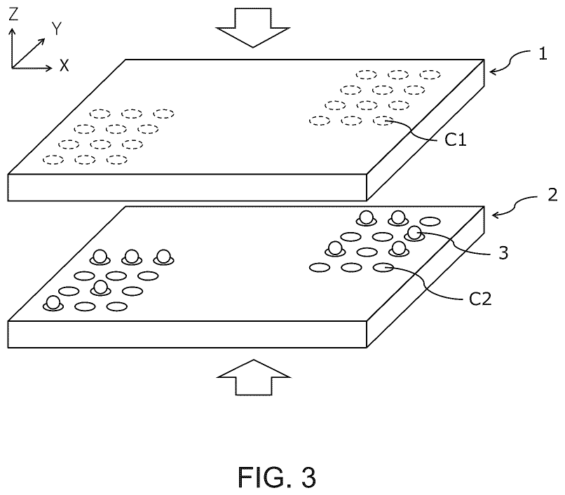

FIG. 3 is a perspective view illustrating a method of manufacturing the semiconductor device of the first embodiment.

FIG. 3 illustrates processing of bonding the upper substrate 1 and the lower substrate 2. More specifically, FIG. 3 illustrates one chip region in the upper substrate 1 (upper wafer) having a wafer shape and one chip region in the lower substrate 2 (lower wafer) having a wafer shape. In the present embodiment, each of the upper and lower wafers includes a plurality of chip regions and a scribe region. In the present embodiment, as illustrated in FIG. 3, the upper and lower wafers are bonded such that each chip region in the upper wafer is disposed on the corresponding chip region in the lower wafer. Thereafter, the upper and lower wafers are cut at the scribe region, and accordingly, a plurality of semiconductor devices (semiconductor chips) are manufactured from the upper and lower wafers. Each semiconductor device has the structure illustrated in FIG. 1 and includes one chip region cut from the upper wafer and one chip region cut from the lower wafer.

FIG. 3 also illustrates the plurality of concave portions C1 provided at the lower face of the upper substrate 1, the plurality of concave portions C2 provided at the upper face of the lower substrate 2, and the plurality of spherical members 3 disposed in the concave portions C2. In FIG. 3, the upper substrate 1 and the lower substrate 2 are bonded such that each concave portion C1 faces the corresponding concave portion C2 and each spherical member 3 is housed in a pair of concave portions C1 and C2. This makes it possible to achieve alignment between the upper substrate 1 and the lower substrate 2 by means of the above-described plurality of spherical members 3.

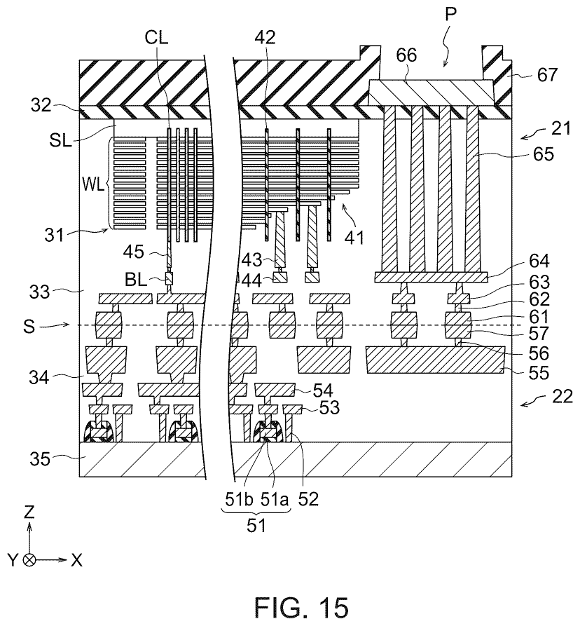

In the present embodiment, the upper substrate 1 (upper wafer) is formed by forming the inter layer dielectric 1b on the substrate 1a having a wafer shape and forming the plurality of metal pads 1c and the plurality of concave portions C1 in the inter layer dielectric 1b on the upper face side of the inter layer dielectric 1b. Similarly, the lower substrate 2 (lower wafer) is formed by forming the inter layer dielectric 2b on the substrate 2a having a wafer shape and forming the plurality of metal pads 2c and the plurality of concave portions C2 in the inter layer dielectric 2b on the upper face side of the inter layer dielectric 2b. Subsequently, the upper and lower wafers are bonded such that the inter layer dielectric 1b is disposed on the inter layer dielectric 2b and the above-described plurality of concave portions C1 are disposed on the above-described plurality of concave portions C2, and thereafter, the upper and lower wafers are cut. Accordingly, the above-described plurality of semiconductor devices (semiconductor chips) are manufactured from the upper and lower wafers. An example of the structure and manufacturing method of the semiconductor device of the present embodiment will be described later in a second embodiment (FIGS. 15 to 18).

Each concave portion C1 of the present embodiment may be formed in any chip region in the upper wafer or may be formed in the scribe region in the upper wafer (in other words, outside the chip regions). Similarly, each concave portion C2 of the present embodiment may be formed in any chip region in the lower wafer or may be formed in the scribe region in the lower wafer (in other words, outside the chip regions). In a case where the concave portions C1 and C2 are formed in the scribe regions, no concave portions C1 and C2 remain in the semiconductor device after cutting of the upper and lower wafers. In this case, since the upper substrate 1 after the cutting is already bonded to the lower substrate 2, the positional relation between the upper substrate 1 and the lower substrate 2 can be maintained even though no concave portions C1 and C2 or spherical members 3 remain in the semiconductor device.

In the present embodiment, the plurality of concave portions C2 for housing the plurality of spherical members 3 may be determined randomly or intentionally. For example, the spherical members 3 can be randomly housed in the plurality of concave portions C2 by scattering the spherical members 3 onto the lower substrate 2 and sweeping the spherical members 3 on the lower substrate 2 with a brush. The spherical members 3 can be housed in the plurality of concave portions C2 of a predetermined pattern by disposing each spherical member 3 in a predetermined concave portion C2 as in a case of forming ball bumps. In the former case, the spherical members 3 can be easily disposed in the concave portions C2. In the latter case, for example, the spherical members 3 can be disposed in the concave portions C2 so as to obtain a high effect of alignment between the upper substrate 1 and the lower substrate 2.

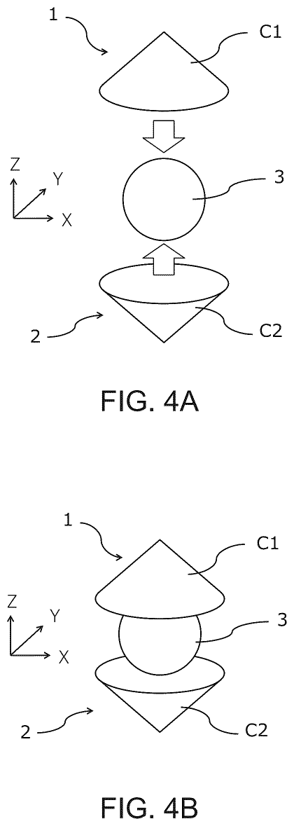

FIGS. 4A and 4B are perspective views illustrating an example of the method of manufacturing the semiconductor device of the first embodiment.

FIGS. 4A and 4B illustrate processing of housing one spherical member 3 in one pair of concave portions C1 and C2. In FIGS. 4A and 4B, the concave portion C1 has a conical shape in which the area of an XY section of the concave portion C1 decreases toward the positive Z direction, and the concave portion C2 has a conical shape in which the area of an XY section of the concave portion C2 decreases toward the negative Z direction. The diameters of the bases of these conical shapes are, for example, 10 to 50 μm.

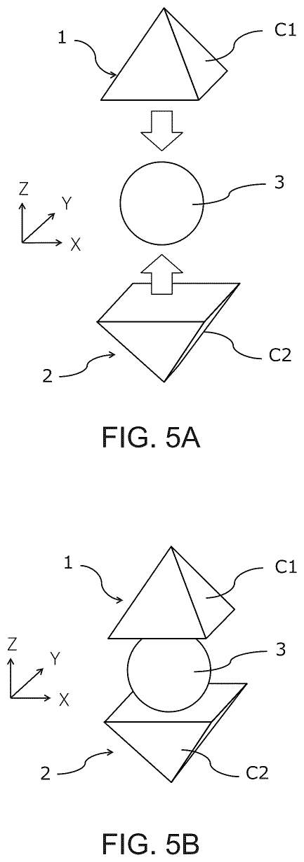

FIGS. 5A and 5B are perspective views illustrating another example of the method of manufacturing the semiconductor device of the first embodiment.

FIGS. 5A and 5B illustrate processing of housing one spherical member 3 in one pair of concave portions C1 and C2. In FIGS. 5A and 5B, the concave portion C1 has a pyramidal shape in which the area of an XY section of the concave portion C1 decreases toward the positive Z direction, and the concave portion C2 has a pyramidal shape in which the area of an XY section of the concave portion C2 decreases toward the negative Z direction. The bases of these pyramidal shapes have, for example, square shapes. A length of each side of the squares is, for example, 10 to 50 μm.

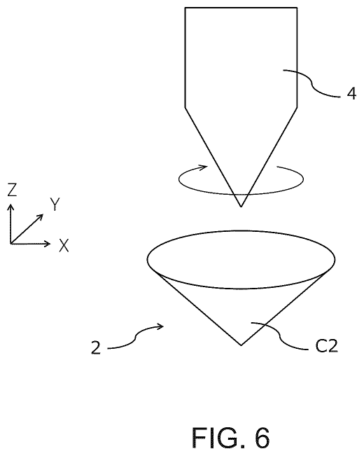

FIG. 6 is a perspective view illustrating the method of manufacturing the semiconductor device of the first embodiment.

FIG. 6 illustrates processing of forming one concave portion C2 in the inter layer dielectric 2b of the lower substrate 2 by using a drill 4. This makes it possible to easily form the concave portion C2 having a conical shape in the inter layer dielectric 2b. Each concave portion C2 of the present embodiment may be formed in the inter layer dielectric 2b of the lower substrate 2 by using another tool. An example of such a tool is a reamer.

Each concave portion C1 of the present embodiment can be formed in the same manner as the concave portion C2. For example, each concave portion C1 may be formed in the inter layer dielectric 1b of the upper substrate 1 by using the drill 4 or a reamer.

### (1) First Modification

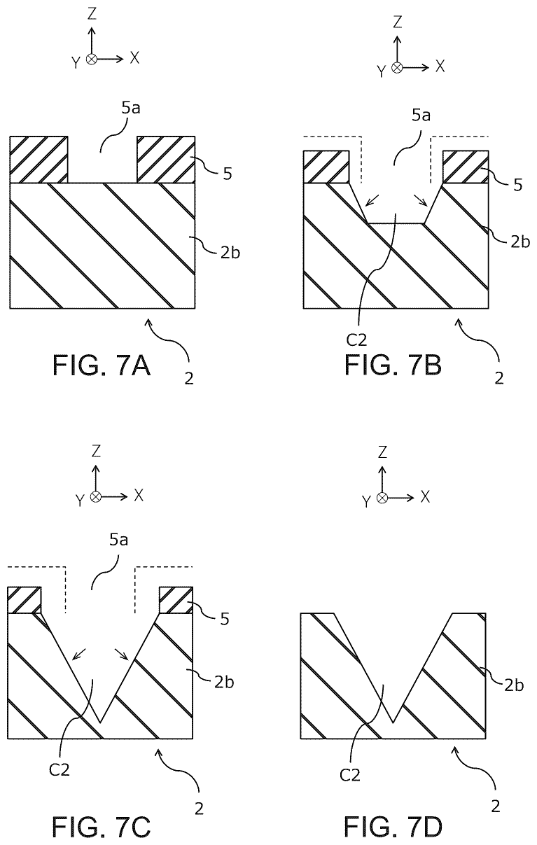

FIGS. 7A to 7D are cross sectional views illustrating a method of manufacturing a semiconductor device of a first modification of the first embodiment. FIGS. 7A to 7D illustrate processing of forming one concave portion C2 in the inter layer dielectric 2b of the lower substrate 2 by etching. This processing is also applicable to the concave portions C1 in the same manner.

First, a resist layer 5 is formed on the inter layer dielectric 2b, and an opening 5a is formed in the resist layer 5 (FIG. 7A). In a case where the concave portion C2 has a conical shape, the opening 5a is set to have a circular shape in a plan view. In a case where the concave portion C2 has a pyramidal shape, the opening 5a is set to have a polygonal shape in a plan view. However, the shape of the opening 5a may be set in consideration of error in lithography and etching.

Subsequently, the resist layer 5 is used as a mask to process the inter layer dielectric 2b below the opening 5a by etching (FIGS. 7B and 7C). FIGS. 7B and 7C illustrate flow of the etching. The etching is, for example, taper etching by reactive ion etching (RIE).

In this manner, the concave portion C2 is formed in the inter layer dielectric 2b (FIG. 7D). The resist layer 5 may disappear during the etching or may be removed after the etching.

The present modification makes it possible to form the concave portions C2 in the inter layer dielectric 2b by using semiconductor process technologies. This makes it possible to form the concave portions C2 in a simple and highly accurate manner in a process of manufacturing semiconductor devices.

### (2) Second Modification

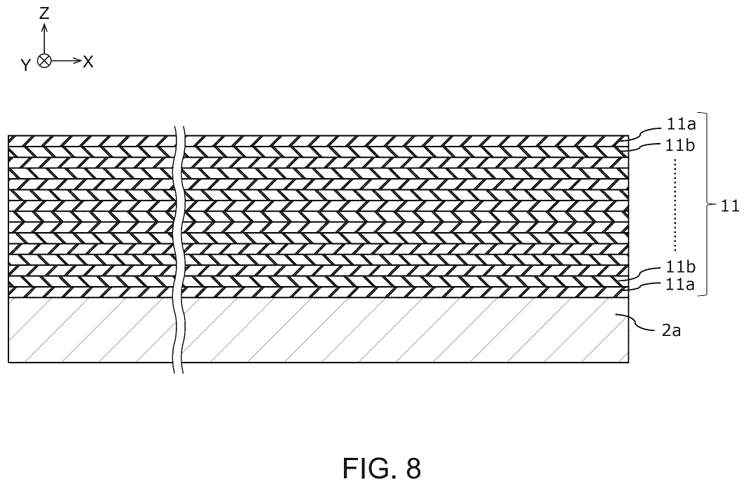

FIGS. 8 to 10 are cross sectional views illustrating a method of manufacturing a semiconductor device of a second modification of the first embodiment. FIGS. 8 to 10 illustrate processing of forming the concave portions C2 in a stacked film 11 included in the inter layer dielectric 2b of the lower substrate 2. This processing is also applicable to the concave portions C1 in the same manner.

First, a plurality of insulators 11a and a plurality of sacrificial layers 11b are alternately formed on the substrate 2a (FIG. 8), and as a result, the stacked film 11 alternately including the plurality of insulators 11a and the plurality of sacrificial layers 11b is formed on the substrate 2a. Each insulator 11a is, for example, a SiO₂ film. Each sacrificial layer 11b is, for example, a silicon nitride film (SiN film). Each sacrificial layer 11b may be an insulator other than a SiO₂ film and a SiN film or may be a semiconductor layer such as a polysilicon layer or an amorphous silicon layer. Similarly to the inter layer dielectric 2b, the stacked film 11 is an example of the first insulator and the first film.

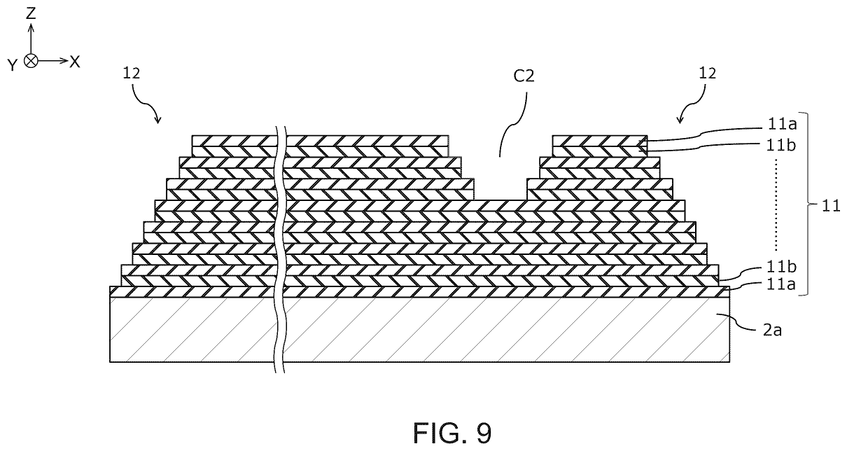

Subsequently, a shape of the stacked film 11 is processed (FIG. 9). As a result, one or more staircase structure portions 12 and at least one concave portion C2 are formed in the stacked film 11. FIG. 9 illustrates a staircase structure portion 12 formed at a right end of the stacked film 11 and a staircase structure portion 12 formed at a left end of the stacked film 11. Each staircase structure portion 12 illustrated in FIG. 9 forms a staircase extending in the X direction, and a pair of an insulator 11a and a sacrificial layer 11b in each staircase structure portion 12 form one step of the staircase. FIG. 9 also illustrates one concave portion C2 formed between the staircase structure portions 12 in the stacked film 11. Similarly to each staircase structure portion 12, the concave portion C2 illustrated in FIG. 9 has a surface in a staircase shape. The processing of the stacked film 11 in FIG. 9 is performed by, for example, etching such as RIE. Through the etching, the staircase structure portions 12 and the concave portion C2 are formed by, for example, slimming.

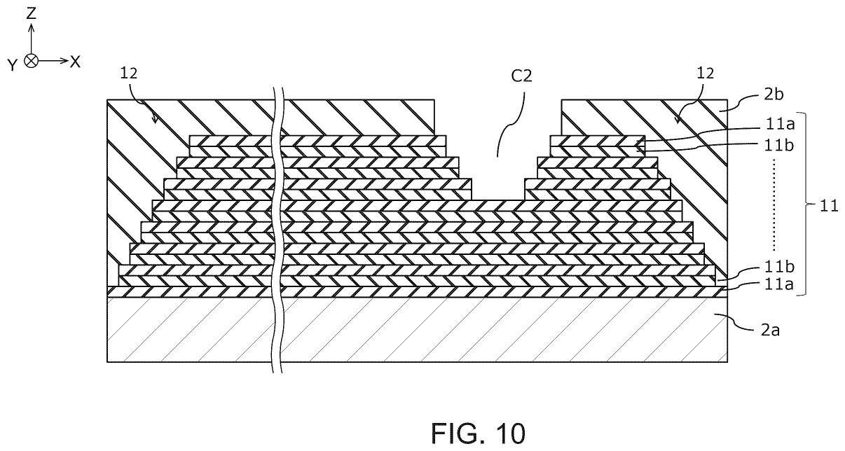

Subsequently, the inter layer dielectric 2b is formed on the substrate 2a so as to cover the stacked film 11 (FIG. 10). As a result, the inter layer dielectric 2b is formed on the staircase structure portions 12 and in the concave portion C2.

Subsequently, the inter layer dielectric 2b is processed by etching so as to remove the inter layer dielectric 2b from the concave portion C2 of the stacked film 11 (FIG. 10). As a result, the concave portion C2 is processed into a shape that extends into the stacked film 11 and the inter layer dielectric 2b. The concave portion C2 may not be formed at the stage in FIG. 9 before the formation of the inter layer dielectric 2b but may be formed at the stage in FIG. 10 after the formation of the inter layer dielectric 2b.

Thereafter, a plurality of slits are formed in the stacked film 11, and a replacement process of replacing the sacrificial layers 11b with electrode layers is performed by using the slits. Accordingly, a memory cell array including the stacked film 11 is formed. An example of the memory cell array is illustrated in FIG. 15 for the second embodiment to be described later.

In the replacement process, only a portion of each sacrificial layer 11b may be replaced with an electrode layer. In this case, the above-described plurality of sacrificial layers 11b remain in respective semiconductor devices of the present embodiment. These sacrificial layers 11b remain, for example, at places far from the above-described plurality of slits and at places close to either staircase structure portion 12. In this case, each staircase structure portion 12 in each semiconductor device may be formed of these sacrificial layers 11b. In a case where the concave portions C2 are formed at places far from the above-described plurality of slits and at places close to either staircase structure portion 12, the concave portions C2 in each semiconductor device may be formed of these sacrificial layers 11b.

The present modification makes it possible to form the concave portions C2 in the inter layer dielectric 2b and the stacked film 11 by using semiconductor process technologies. This makes it possible to form the concave portions C2 in a simple and highly accurate manner in a process of manufacturing semiconductor devices as in the second modification.

### (3) Third to Fifth Modifications

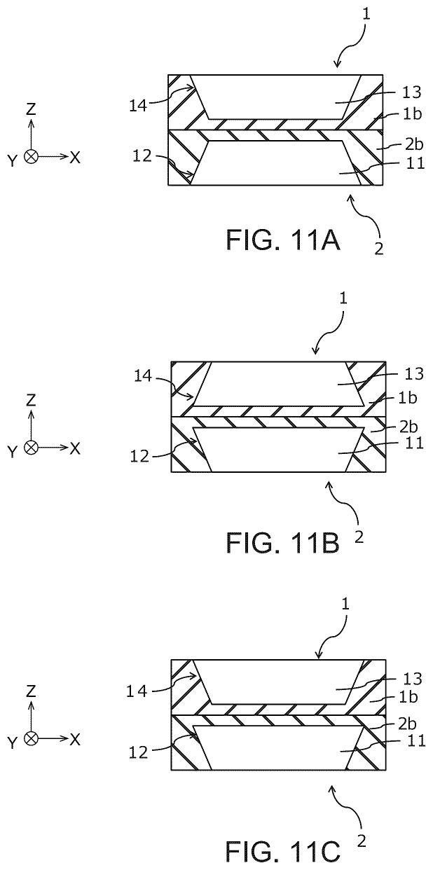

FIGS. 11A to 11C are cross sectional views for describing methods of manufacturing semiconductor devices of third to fifth modifications of the first embodiment.

FIG. 11A illustrates the stacked film 11 in the inter layer dielectric 2b of the lower substrate 2, one or more staircase structure portions 12 included in the stacked film 11, a stacked film 13 in the inter layer dielectric 1b of the upper substrate 1, and one or more staircase structure portions 14 included in the stacked film 13. As described above, similarly to the inter layer dielectric 2b, the stacked film 11 is an example of the first insulator and the first film. Similarly to the inter layer dielectric 1b, the stacked film 13 is an example of the second insulator and the second film.

Structures and formation methods of the stacked film 11 and the staircase structure portions 12 illustrated in FIG. 11A are the same as the structures and formation methods of the stacked film 11 and the staircase structure portions 12 illustrated in FIGS. 8 to 10. In addition, structures and formation methods of the stacked film 13 and the staircase structure portions 14 illustrated in FIG. 11A are the same as the structures and formation methods of the stacked film 11 and the staircase structure portions 12 illustrated in FIGS. 8 to 10.

In FIG. 11A, the stacked film 11 has an approximately trapezoidal XZ sectional shape in which a side of the stacked film 11 on the upper face side is shorter than a side of the stacked film 11 on the lower face side. In this case, the upper face of the stacked film 11 is referred to as “face”, and the lower face of the stacked film 11 is referred to as “back”. In addition, in FIG. 11A, the stacked film 13 has an approximately trapezoidal XZ sectional shape in which a side of the stacked film 13 on the lower face side is shorter than a side of the stacked film 13 on the upper face side. In this case, the lower face of the stacked film 13 is referred to as “face”, and the upper face of the stacked film 13 is referred to as “back”. The stacked films 11 and 13 illustrated in FIG. 11A have a “face-to-face structure”.

FIG. 11B, as well, illustrates the stacked film 11, one or more staircase structure portions 12, the stacked film 13, and one or more staircase structure portions 14. However, in FIG. 11B, the stacked film 11 has an approximately trapezoidal XZ sectional shape in which the side of the stacked film 11 on the lower face side is shorter than the side of the stacked film 11 on the upper face side. In addition, in FIG. 11B, the stacked film 13 has an approximately trapezoidal XZ sectional shape in which the side of the stacked film 13 on the upper face side is shorter than the side of the stacked film 13 on the lower face side. The stacked films 11 and 13 illustrated in FIG. 11B have a “back-to-back structure”.

FIG. 11C, as well, illustrates the stacked film 11, one or more staircase structure portions 12, the stacked film 13, and one or more staircase structure portions 14. However, in FIG. 11C, the stacked film 11 has an approximately trapezoidal XZ sectional shape in which the side of the stacked film 11 on the lower face side is shorter than the side of the stacked film 11 on the upper face side. In addition, in FIG. 11C, the stacked film 13 has an approximately trapezoidal XZ sectional shape in which the side of the stacked film 13 on the lower face side is shorter than the side of the stacked film 13 on the upper face side. The stacked films 11 and 13 illustrated in FIG. 11C have a “face-to-back structure”.

In each of FIGS. 11A to 11C, as in the second modification, one or more concave portions C2 may be formed in the stacked film 11, and one or more concave portions C1 may be formed in the stacked film 13. This makes it possible to form the concave portions C1 and C2 by using semiconductor process technologies.

In FIG. 11A, the concave portions C1 and C2 may be formed by using the staircase structure portions 12 and 14. In this case, two stacked films 11 are formed in the lower substrate 2, and a region between a staircase structure portion 12 of one of the stacked films 11 and a staircase structure portion 12 of the other stacked film 11 is used as a concave portion C2. Similarly, two stacked films 13 are formed in the upper substrate 1, and a region between a staircase structure portion 14 of one of the stacked films 13 and a staircase structure portion 14 of the other stacked film 13 is used as a concave portion C1. In this case, the surface of each staircase structure portion 12 serves as the surface of the concave portion C2, and the surface of each staircase structure portion 14 serves as the surface of the concave portion C1.

This method is also applicable to the upper substrate 1 in FIG. 11C. In FIG. 11C, a concave portion C1 of the upper substrate 1 is formed between two staircase structure portions 14, and a concave portion C2 of the lower substrate 2 is formed in the stacked film 11.

### (4) Sixth Modification

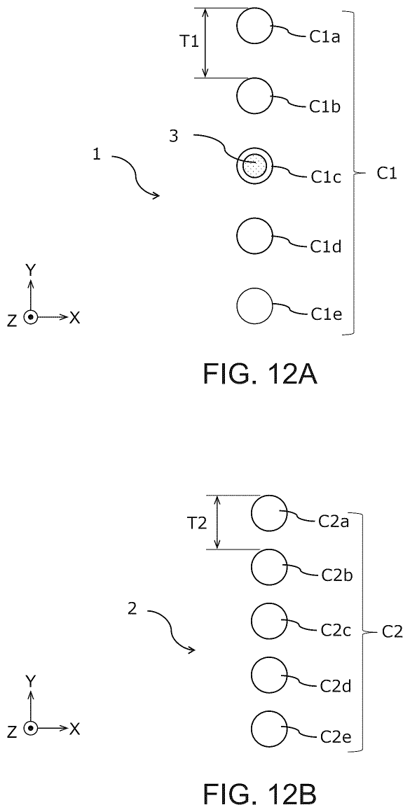

FIGS. 12A and 12B are plan views for describing a method of manufacturing a semiconductor device of a sixth modification of the first embodiment.

FIG. 12A illustrates the plurality of concave portions C1 provided in the upper substrate 1. These concave portions C1 include five concave portions C1a to C1e arranged in line in the Y direction. FIG. 12A also illustrates a pitch T1 between the concave portions C1a to C1e.

FIG. 12B illustrates the plurality of concave portions C2 provided in the lower substrate 2. These concave portions C2 include five concave portions C2a to C2e arranged in line in the Y direction. FIG. 12B also illustrates a pitch T2 between the concave portions C2a to C2e. In the present modification, the pitch T2 is different from the pitch T1.

In the present modification, a bonding position between the upper substrate 1 and the lower substrate 2 is adjusted by bonding the upper substrate 1 and the lower substrate 2 such that a spherical member 3 is housed in a predetermined concave portion C1 among the concave portions C1a to C1e and in a predetermined concave portion C2 among the concave portions C2a to C2e. In a case, the upper substrate 1 and the lower substrate 2 are bonded such that the concave portion C1c faces the concave portion C2c and a spherical member 3 is housed in the concave portions C1c and C2c. In another case, the upper substrate 1 and the lower substrate 2 are bonded such that the concave portion C1a faces the concave portion C2a and a spherical member 3 is housed in the concave portions C1a and C2a.

In the present modification, the concave portions C1 and C2 are formed in the upper substrate 1 and the lower substrate 2 in consideration of cases where warpage or distortion occurs in at least one of the upper substrate 1 and the lower substrate 2.

For example, in a case where no warpage or distortion occurs in the upper substrate 1 and the lower substrate 2, the concave portions C1 and C2 are formed such that the concave portion C1c faces the concave portion C2c. Thus, in a case where no warpage or distortion occurs in the upper substrate 1 and the lower substrate 2, the upper substrate 1 and the lower substrate 2 are bonded such that a spherical member 3 is housed in the concave portions C1c and C2c. This makes it possible to excellently bond the upper substrate 1 and the lower substrate 2 in a case where no warpage or distortion occurs.

However, in a case where warpage and/or distortion occurs in the upper substrate 1 and/or the lower substrate 2, the upper substrate 1 and the lower substrate 2 are bonded such that a spherical member 3 is housed in a concave portion C1 other than the concave portion C1c and in a concave portion C2 other than the concave portion C2c. For example, the upper substrate 1 and the lower substrate 2 are bonded such that spherical members 3 are housed in the concave portions C1a and C2a, in the concave portions C1b and C2b, in the concave portions C1d and C2d, or in the concave portions C1e and C2e. This makes it possible to excellently bond the upper substrate 1 and the lower substrate 2 in a case where warpage and/or distortion occurs.

In the present modification, instead of making the pitch T2 different from the pitch T1, the sizes of the concave portions C1a to C1e may be made different from each other and the sizes of the concave portions C2a to C2e may be made different from each other. This makes it possible to adjust the bonding position between the upper substrate 1 and the lower substrate 2 by using such size difference.

For example, a case is assumed where the concave portions C1a to C1e include large and small concave portions C1, and the concave portions C2a to C2e include large and small concave portions C2, and difference between the sizes of the large concave portions C1 and C2 and the sizes of the small concave portions C1 and C2 is sufficiently large.

In this case, a spherical member 3 as large as the large concave portions C1 and C2 can enter the large concave portions C1 and C2 but cannot enter the small concave portions C1 and C2. Accordingly, the bonding position between the upper substrate 1 and the lower substrate 2 can be adjusted by using the large concave portions C1 and C2 and a large spherical member 3.

A spherical member 3 as small as the small concave portions C1 and C2 can enter the small concave portions C1 and C2 and the large concave portions C1 and C2. However, a small spherical member 3 having entered the large concave portions C1 and C2 can significantly move in the large concave portions C1 and C2, and thus cannot appropriately contribute to adjustment of the bonding position. Thus, only a small spherical member 3 having entered the small concave portions C1 and C2 can appropriately contribute to adjustment of the bonding position. Accordingly, the bonding position between the upper substrate 1 and the lower substrate 2 can be adjusted by using the small concave portions C1 and C2 and a small spherical member 3.

This is also the same for a case where the concave portions C1a to C1e include concave portions C1 of Na different sizes (where Na is an integer equal to or larger than two) and the concave portions C2a to C2e include concave portions C2 of Nb different sizes (Nb is an integer equal to or larger than two). Nb is typically a value equal to Na but may be a value different from Na.

### (5) Seventh Modification

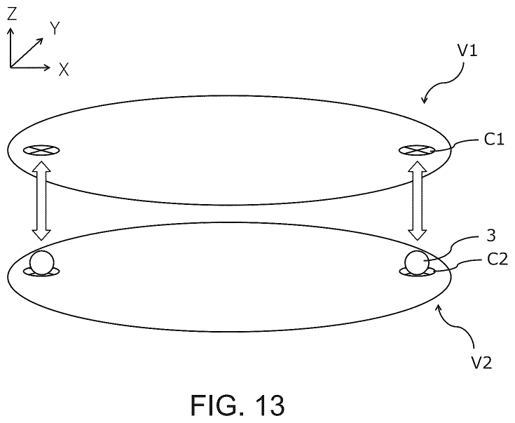

FIG. 13 is a perspective view illustrating a method of manufacturing a semiconductor device of a seventh modification of the first embodiment.

FIG. 13 illustrates an upper wafer V1 that is the upper substrate 1 having a wafer shape, and a lower wafer V2 that is the lower substrate 2 having a wafer shape. FIG. 13 also illustrates a plurality of concave portions C1 formed outside a chip region of the upper wafer V1 on a lower face of the upper wafer V1, and a plurality of concave portions C2 formed outside a chip region of the lower wafer V2 on an upper face of the lower wafer V2. In FIG. 13, the upper substrate 1 and the lower substrate 2 are bonded such that spherical members 3 are housed in the concave portions C1 and C2. Each of the concave portions C1 and C2 is formed by using, for example, the drill 4 (FIG. 6) or a reamer.

The present modification makes it possible to, for example, form large concave portions C1 and C2 by forming the concave portions C1 and C2 outside the chip regions of the upper wafer V1 and the lower wafer V2. This makes it possible to easily form the concave portions C1 and C2 and easily handle the spherical members 3.

### (6) Eighth Modification

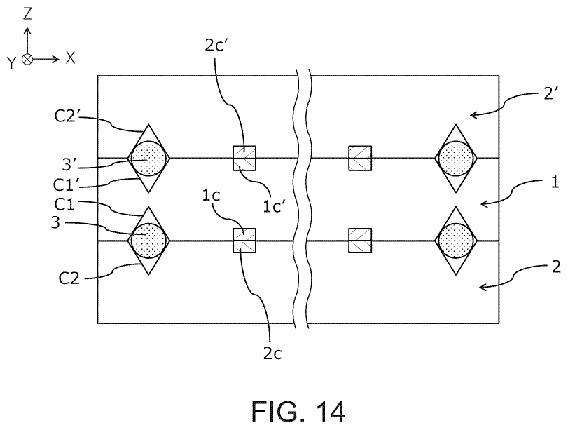

FIG. 14 is a plan view illustrating the structure of a semiconductor device of an eighth modification of the first embodiment.

The semiconductor device of the present modification includes an upper substrate 2′ in addition to the upper substrate 1 and the lower substrate 2. The upper substrate 2′ is bonded to the upper substrate 1. Accordingly, the upper substrate 2′ is disposed on the upper substrate 1 and in contact with the upper substrate 1. The upper substrate 1 corresponds to a “lower substrate” for the upper substrate 2′.

In the present modification, the substrate 1a (refer to FIG. 1) is removed from the upper substrate 1 since the upper substrate 2′ is bonded to the upper substrate 1. Instead, the upper substrate 1 includes a plurality of metal pads 1c′ and a plurality of concave portions C1′ provided in the inter layer dielectric 1b (refer to FIG. 1) on the upper face side of the upper substrate 1. Moreover, the upper substrate 2′ includes a plurality of metal pads 2c′ and a plurality of concave portions C2′ disposed on the metal pads 1c′ and the concave portions C1′ on the lower face side of the upper substrate 2′. The semiconductor device of the present modification also includes a plurality of spherical members 3′, and each spherical member 3′ is housed in a pair of concave portions C1′ and C2′.

The present modification makes it possible to perform, when three or more substrates (the upper substrate 1, the lower substrate 2, and the upper substrate 2′) are bonded, alignment of these substrates by using a plurality of members (spherical members 3 and 3′).

As described above, as illustrated in FIG. 1, the semiconductor device of the present embodiment includes the spherical members 3 housed in the concave portions C1 and C2 of the upper substrate 1 and the lower substrate 2. Accordingly, the present embodiment makes it possible to excellently bond the upper substrate 1 and the lower substrate 2 by, for example, performing alignment between the upper substrate 1 and the lower substrate 2 by using the spherical members 3.

The semiconductor device illustrated in FIG. 1 may not include at least one of the substrates 1a and 2a. Examples of such a structure are the structure illustrated in FIG. 14 described above and a structure illustrated in FIG. 15 to be described later. Each concave portion C1 illustrated in FIG. 1 may be formed in the substrate 1a and/or the inter layer dielectric 1b, and each concave portion C2 illustrated in FIG. 1 may be formed in the substrate 2a and/or the inter layer dielectric 2b. For example, the concave portion C2 illustrated in FIG. 7D may reach the substrate 2a.

### Second Embodiment

FIG. 15 is a cross sectional view illustrating the structure of a semiconductor device of the second embodiment. The semiconductor device of the present embodiment is, for example, a three-dimensional semiconductor memory.

The semiconductor device of the present embodiment includes an array chip 21 and a circuit chip 22 bonded to each other. As described later, the semiconductor device of the present embodiment is manufactured by bonding an array wafer including the array chip 21 and a circuit wafer including the circuit chip 22. The array chip 21 and the circuit chip 22 of the present embodiment correspond to the upper substrate 1 and the lower substrate 2 of the first embodiment, respectively.

The array chip 21 includes a memory cell array 31 including a plurality of memory cells, an insulator 32 on the memory cell array 31, and an inter layer dielectric 33 below the memory cell array 31. The insulator 32 is, for example, a SiO₂ film. The inter layer dielectric 33 is, for example, a stacked film including a SiO₂ film and other insulators. A portion of the memory cell array 31 of the present embodiment corresponds to the stacked film 11 or 13 of the first embodiment, and the inter layer dielectric 33 of the present embodiment corresponds to the inter layer dielectric 1b of the first embodiment.

The circuit chip 22 is provided below the array chip 21. Reference sign S denotes a bonding face of the array chip 21 and the circuit chip 22. The circuit chip 22 includes an inter layer dielectric 34 below the inter layer dielectric 33, and a substrate 35 below the inter layer dielectric 34. The inter layer dielectric 34 is, for example, a stacked film including a SiO₂ film and other insulators. The substrate 35 is, for example, a semiconductor substrate such as a Si substrate. The inter layer dielectric 34 and the substrate 35 of the present embodiment correspond to the inter layer dielectric 2b and the substrate 2a of the first embodiment, respectively.

FIG. 15 illustrates an X direction and a Y direction parallel to the surface of the substrate 35 and orthogonal to each other, and a Z direction orthogonal to the surface of the substrate 35. The X direction, the Y direction, and the Z direction intersect one another. In the present embodiment, as in the first embodiment, the positive Z direction is the upward direction, and the negative Z direction is the downward direction. The negative Z direction may or may not be aligned with the direction of gravity.

The array chip 21 includes a plurality of word lines WL as a plurality of electrode layers in the memory cell array 31. FIG. 15 illustrates a staircase structure portion 41 in the memory cell array 31, and a plurality of beam portions 42 provided in the staircase structure portion 41. Each word line WL extends in the X direction and is electrically connected to a word interconnect layer 44 through a contact plug 43. Each column-shaped portion CL penetrating through the plurality of word lines WL is electrically connected to a bit line BL through a via plug 45 and electrically connected to a source line SL. The bit line BL extends in the Y direction and is provided below the plurality of word lines WL. The source line SL extends in the X direction and is provided above the plurality of word lines WL. The staircase structure portion 41 of the present embodiment corresponds to a staircase structure portion 12 or 14 of the first embodiment.

The circuit chip 22 includes a plurality of transistors 51. Each transistor 51 includes a gate insulator 51a and a gate electrode 51b sequentially provided on the substrate 35, and a source diffusion layer and a drain diffusion layer provided in the substrate 35, which are not illustrated. The circuit chip 22 includes a plurality of contact plugs 52 each provided on the gate electrode 51b, the source diffusion layer, or the drain diffusion layer of the corresponding one of the plurality of transistors 51. The circuit chip 22 also includes an interconnect layer 53, an interconnect layer 54, and an interconnect layer 55. The interconnect layer 53 includes a plurality of interconnects and is provided on the plurality of contact plugs 52. The interconnect layer 54 includes a plurality of interconnects and is provided on the interconnect layer 53. The interconnect layer 55 includes a plurality of interconnects and is provided on the interconnect layer 54.

The circuit chip 22 further includes a plurality of via plugs 56 provided on the interconnect layer 55, and a plurality of metal pads 57 provided on the plurality of via plugs 56. The metal pads 57 are, for example, a metal layer including a Cu layer. The circuit chip 22 functions as a logic circuit that controls operation of the array chip 21. The logic circuit is constituted by the transistors 51 and the like and electrically connected to the metal pads 57. The metal pads 57 of the present embodiment correspond to the metal pads 2c of the first embodiment.

The array chip 21 includes a plurality of metal pads 61 provided on the plurality of metal pads 57, and a plurality of via plugs 62 provided on the plurality of metal pads 61. The metal pads 61 are, for example, a metal layer including a Cu layer. The array chip 21 also includes an interconnect layer 63 and an interconnect layer 64. The interconnect layer 63 includes a plurality of interconnects and is provided on the plurality of via plugs 62. The interconnect layer 64 includes a plurality of interconnects and is provided on the interconnect layer 63. The above-described bit line BL is included in the interconnect layer 64. The above-described logic circuit is electrically connected to the memory cell array 31 through the metal pads 61 and 57 and the like and controls operation of the memory cell array 31 through the metal pads 61 and 57 and the like. The metal pads 61 of the present embodiment correspond to the metal pads 1c of the first embodiment.

The array chip 21 further includes a plurality of via plugs 65 provided on the interconnect layer 64, and a metal pad 66 provided on the plurality of via plugs 65 and the insulator 32. The array chip 21 also includes a passivation insulator 67 provided on the metal pad 66 and the insulator 32. The metal pad 66 is, for example, a metal layer including a Cu layer and functions as an external connection pad (bonding pad) of the semiconductor device of the present embodiment. The passivation insulator 67 is, for example, a stacked film including a SiO₂ film and a SiN film and has an opening P through which the upper face of the metal pad 66 is exposed. The metal pad 66 is electrically connectable to a mounting substrate or other devices through the opening P by a bonding wire, a soldering ball, a metal bump, or the like.

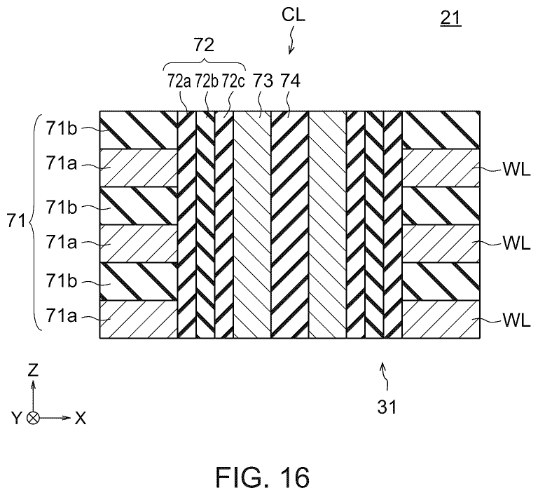

FIG. 16 is an enlarged cross-sectional view illustrating the structure of the semiconductor device of the second embodiment.

FIG. 16 illustrates the memory cell array 31 illustrated in FIG. 15. The memory cell array 31 includes a stacked film 71 including a plurality of electrode layers 71a and a plurality of insulators 71b alternately stacked in the Z direction. The plurality of electrode layers 71a function as, for example, the above-described word lines WL. Each electrode layer 71a is, for example, a metal layer including a Cu layer. Each insulator 71b is, for example, a SiO₂ film. The stacked film 71 of the present embodiment corresponds to the stacked film 11 or 13 of the first embodiment.

FIG. 16 further illustrates one of the plurality of column-shaped portions CL illustrated in FIG. 15. Each column-shaped portion CL includes a memory insulator 72, a channel semiconductor layer 73, and a core insulator 74 sequentially provided on the side face of the stacked film 71. The memory insulator 72 includes a block insulator 72a, an electric charge accumulation layer 72b, and a tunnel insulator 72c sequentially provided on the side face of the stacked film 71. The block insulator 72a is, for example, a SiO₂ film. The electric charge accumulation layer 72b is, for example, an insulator such as a SiN film. The electric charge accumulation layer 72b may be a semiconductor layer such as a polysilicon layer. The electric charge accumulation layer 72b can accumulate signal electric charge of the three-dimensional semiconductor memory. The tunnel insulator 72c is, for example, a SiO₂ film. The channel semiconductor layer 73 is, for example, a polysilicon layer. The channel semiconductor layer 73 functions as a channel of the three-dimensional semiconductor memory. The core insulator 74 is, for example, a SiO₂ film.

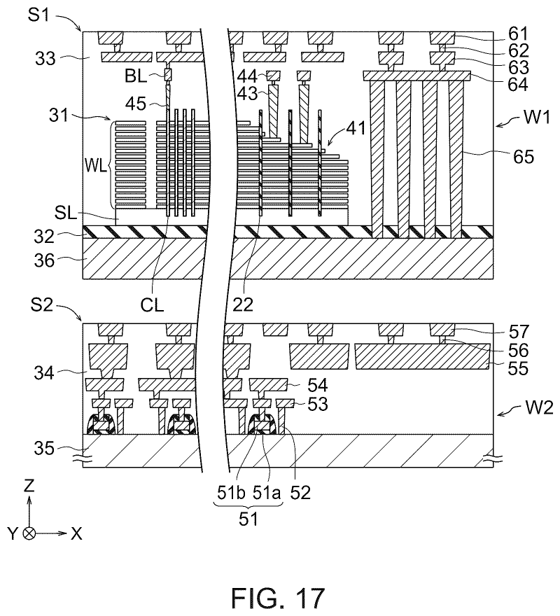

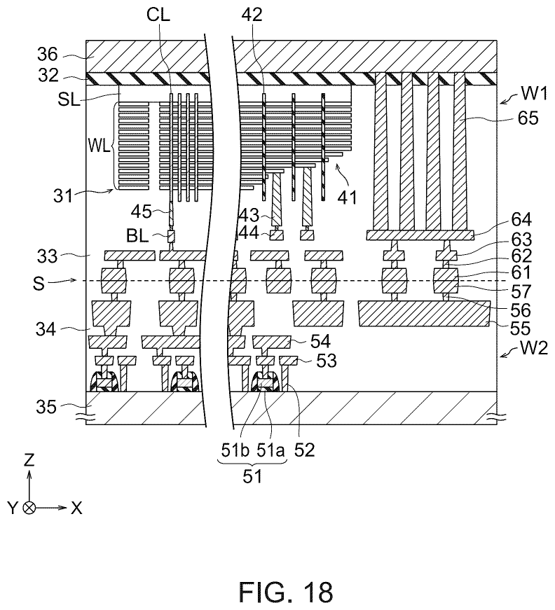

FIGS. 17 and 18 are cross-sectional views illustrating a method of manufacturing the semiconductor device of the second embodiment.

FIG. 17 illustrates an array wafer W1 including a plurality of array chips 21, and a circuit wafer W2 including a plurality of circuit chips 22. The orientation of the array wafer W1 in FIG. 17 is opposite the orientation of the array chip 21 in FIG. 15. In the present embodiment, the semiconductor device is manufactured by bonding the array wafer W1 and the circuit wafer W2. FIG. 17 illustrates the array wafer W1, the orientation of which is yet to be inverted for bonding, and FIG. 15 illustrates the array chip 21, the orientation of which is inverted for bonding and that is bonded and diced.

In FIG. 17, reference sign S1 denotes the upper face of the array wafer W1, and reference sign S2 denotes the upper face of the circuit wafer W2. The array wafer W1 includes a substrate 36 provided below the insulator 32. The substrate 36 is, for example, a semiconductor substrate such as a Si substrate. The substrate 36 of the present embodiment corresponds to the substrate 1a of the first embodiment.

In the present embodiment, first, the memory cell array 31, the insulator 32, the inter layer dielectric 33, the metal pads 61, the via plugs 65, and the like are formed on the substrate 36 of the array wafer W1, and the inter layer dielectric 34, the transistors 51, the metal pads 57, and the like are formed on the substrate 35 of the circuit wafer W2 as illustrated in FIG. 17. Subsequently, the array wafer W1 and the circuit wafer W2 are bonded to each other by mechanical pressure such that the face S1 and the face S2 face each other as illustrated in FIG. 18. Accordingly, the inter layer dielectric 33 and the inter layer dielectric 34 are bonded to each other. Subsequently, the array wafer W1 and the circuit wafer W2 are annealed. Accordingly, the metal pads 61 and the metal pads 57 are joined to each other. In this manner, the substrate 36 and the substrate 35 are bonded to each other through the inter layer dielectrics 33 and 34.

Thereafter, the substrate 36 is removed by chemical mechanical polishing (CMP) and the substrate 35 is thinned by CMP, and then the array wafer W1 and the circuit wafer W2 are cut into a plurality of chips (dicing). In this manner, the semiconductor device illustrated in FIG. 15 is manufactured. The metal pad 66 and the passivation insulator 67 are formed on the insulator 32 after the removal of the substrate 36 and the thinning of the substrate 35.

Although FIG. 15 illustrates the boundary face between the inter layer dielectric 33 and the inter layer dielectric 34 and the boundary face between the metal pads 61 and the metal pads 57, these boundary faces are typically not observed after the above-described annealing. However, the positions of the boundary faces can be estimated by detecting, for example, the tilt of the side face of both the metal pads 61 and the metal pads 57, and positional shift between the side face of the metal pads 61 and the side face of the metal pads 57.

In the present embodiment, as in the first embodiment, a plurality of concave portions C1 are formed in the inter layer dielectric 33, a plurality of concave portions C2 are formed in the inter layer dielectric 34, and spherical members 3 in the concave portions C1 and C2 are used for alignment of bonding. This makes it possible to excellently bond the array wafer W1 and the circuit wafer W2.

The present embodiment makes it possible to apply the semiconductor device of the first embodiment and the method of manufacturing the same to the present embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a lower substrate including a first substrate, a first insulator provided on the first substrate, a first pad provided in the first insulator on an upper face side of the first insulator, and a first concave portion provided in the first insulator on the upper face side of the first insulator;
an upper substrate disposed on the lower substrate and in contact with the lower substrate, the upper substrate including a second substrate, a second insulator provided below the second substrate, a second pad provided in the second insulator on a lower face side of the second insulator, and a second concave portion provided in the second insulator on the lower face side of the second insulator and facing the first concave portion; and
a first member housed in the first concave portion and the second concave portion.

2. The device of claim 1, wherein
the second insulator is disposed on the first insulator, and
the second pad is disposed on the first pad.

3. The device of claim 1, wherein the first member has a spherical shape.

4. The device of claim 1, wherein the first member is formed of glass or metal.

5. The device of claim 1, wherein the first member is housed in the first concave portion and the second concave portion in a state that the first member is in contact with the first insulator and the second insulator.

6. The device of claim 1, wherein at least one of the first concave portion and the second concave portion has a conical shape or a pyramidal shape.

7. The device of claim 1, wherein at least one of a surface of the first concave portion and a surface of the second concave portion has a tapered shape.

8. The device of claim 1, wherein a shape of the first concave portion in a plan view and a shape of the second concave portion in a plan view are congruent.

9. The device of claim 1, wherein
the lower substrate includes, as the first concave portion, a plurality of first concave portions,
the upper substrate includes, as the second concave portion, a plurality of second concave portions, and
one or more of the plurality of second concave portions face one or more of the plurality of first concave portions, respectively.

10. The device of claim 9, wherein
each of the first substrate and the second substrate has a shape of a quadrilateral in a plan view,
the plurality of first concave portions and the plurality of second concave portions respectively include a first concave portion and a second concave portion that are provided in a vicinity of a first corner of the quadrilateral, and a first concave portion and a second concave portion that are provided in a vicinity of a second corner of the quadrilateral, and
the second corner is positioned on a diagonal line of the quadrilateral with respect to the first corner.

11. The device of claim 9, wherein a pitch between the plurality of second concave portions is different from a pitch between the plurality of first concave portions, or the plurality of first concave portions include first concave portions of a plurality of different sizes and the plurality of second concave portions include second concave portions of a plurality of different sizes.

12. A method of manufacturing a semiconductor device, comprising:
forming a lower substrate that includes a first substrate, a first insulator provided on the first substrate, a first pad provided in the first insulator on an upper face side of the first insulator, and a first concave portion provided in the first insulator on the upper face side of the first insulator;
forming an upper substrate that includes a second substrate, a second insulator provided on the second substrate, a second pad provided in the second insulator on an upper face side of the second insulator, and a second concave portion provided in the second insulator on the upper face side of the second insulator; and
bonding the lower substrate and the upper substrate such that the second concave portion faces the first concave portion to house a first member in the first concave portion and the second concave portion.

13. The method of claim 12, wherein the lower substrate and the upper substrate are bonded such that the second insulator is disposed on the first insulator and the second pad is disposed on the first pad.

14. The method of claim 12, wherein
the first concave portion is provided inside a chip region of the lower substrate, and
the second concave portion is provided inside a chip region of the upper substrate.

15. The method of claim 12, wherein
the first concave portion is provided outside a chip region of the lower substrate, and
the second concave portion is provided outside a chip region of the upper substrate.

16. The method of claim 12, wherein the first concave portion or the second concave portion is formed in the first insulator or the second insulator by using a drill or a reamer, or is formed in the first insulator or the second insulator by etching.

17. The method of claim 12, wherein the first concave portion or the second concave portion is formed in a stacked film that is included in the first insulator or the second insulator, or is formed by using a staircase structure portion in the stacked film.

18. The method of claim 12, wherein
the lower substrate is formed to include, as the first concave portion a plurality of first concave portions,
the upper substrate is formed to include, as the second concave portion, a plurality of second concave portions, and
the lower substrate and the upper substrate are bonded such that one or more of the plurality of second concave portions face one or more of the plurality of first concave portions, respectively.

19. The method of claim 18, wherein
a pitch between the plurality of second concave portions is different from a pitch between the plurality of first concave portions, or the plurality of first concave portions include first concave portions of a plurality of different sizes and the plurality of second concave portions include second concave portions of a plurality of different sizes, and
the method further includes adjusting a bonding position between the lower substrate and the upper substrate by bonding the lower substrate and the upper substrate such that the first member is housed in a predetermined first concave portion among the plurality of first concave portions and in a predetermined second concave portion among the plurality of second concave portions.

20. A semiconductor device comprising:
a lower chip including a first substrate and/or a first film, and a first concave portion provided in the first substrate and/or in the first film;
an upper chip disposed on the lower chip and in contact with the lower chip, the upper chip including a second substrate and/or a second film, and a second concave portion provided in the second substrate and/or in the second film and facing the first concave portion; and
a first member housed in the first concave portion and the second concave portion.
